(19) United States
(12) Patent Application Publication
(10) Pub. No.: US 2024/0231219 A1
(43) Pub. Date: Jul. 11, 2024

(54) HARD MASK AND SEMICONDUCTOR DEVICE COMPRISING THE SAME

(71) Applicant: Samsung Electronics Co., Ltd., Suwon-si (KR)

(72) Inventors: Nam Jin CHO, Suwon-si (KR); Yi Hwan KIM, Suwon-si (KR); Seok Jun HONG, Suwon-si (KR); Seong Keun CHO, Suwon-si (KR); Sang Chul HAN, Suwon-si (KR)

(73) Assignee: Samsung Electronics Co., Ltd., Suwon-si (KR)

(21) Appl. No.: 18/469,743

(22) Filed: Sep. 19, 2023

(30) Foreign Application Priority Data
Jan. 9, 2023 (KR) 10-2023-0002724

(51) Int. Cl. G03F 1/48; G03F 1/60; H01L 21/02; H01L 21/033

(52) U.S. Cl. CPC G03F 1/48; G03F 1/60; H01L 21/02592; H01L 21/0332

(57) ABSTRACT

A hard mask may include a first layer and a second layer on the first layer. Each of the first layer and the second layer may include an amorphous carbon layer. The first layer may have a first extinction coefficient. The second layer may have a second extinction coefficient and the second extinction coefficient may be different from the first extinction coefficient. The first extinction coefficient and the second extinction coefficient each may be in a range of 0.4 to 0.7.

### CROSS-REFERENCE TO RELATED APPLICATION

This application claims priority from Korean Patent Application No. 10-2023-0002724, filed on Jan. 9, 2023 in the Korean Intellectual Property Office, and all the benefits accruing therefrom under 35 U.S.C. 119, the entire contents of which are herein incorporated by reference.

### BACKGROUND

### Field

The present disclosure relates to a hard mask and/or a semiconductor device including the same.

### Description of Related Art

As semiconductor manufacturing technology develops, an integration density of a semiconductor device is increasing, and accordingly, a size of the semiconductor device is being increasingly smaller. As the semiconductor device is increasingly miniaturized, a wavelength of light used for an exposure process is shortened. Accordingly, a thickness of a photoresist film becomes smaller, such that it may become difficult to accurately implement a vertical profile. Thus, an amorphous carbon layer (ACL) is currently used as a hard mask.

However, with the miniaturization of the semiconductor device, high film quality of the hard mask may be required. When a process temperature is increased to improve the film quality of the hard mask, a stress applied to a wafer may increase. Wafer chucking error, arcing-related defect, and contamination in a chamber may occur due to the increased stress applied to the wafer. Thus, a hard mask having improved film quality and allowing reduced wafer stress may be required.

### SUMMARY

An aspect of the present disclosure provides a hard mask that can reduce wafer stress and/or improve an etch selectivity.

Another aspect of the present disclosure provides a semiconductor device which can reduce wafer stress and/or improve an etch selectivity.

Aspects of the present disclosure are not limited to those mentioned above and additional aspects of the present disclosure, which are not mentioned herein, will be clearly understood by those skilled in the art from the following description of the present disclosure.

According to an embodiment of the present disclosure, a hard mask may include a first layer; and a second layer on the first layer. The first layer and the second layer each may include an amorphous carbon layer. The first layer may have a first extinction coefficient. The second layer may have a second extinction coefficient. The second extinction coefficient may be different from the first extinction coefficient. The first extinction coefficient and the second extinction coefficient each may be in a range of 0.4 to 0.7.

According to an embodiment of the present disclosure, a hard mask may include an amorphous carbon layer having a first layer and a second layer on the first layer. An extinction coefficient of the hard mask may be in a range of 0.4 to 0.7. The first layer may have a first extinction coefficient. The second layer may have a second extinction coefficient. The second extinction coefficient may be different from the first extinction coefficient.

According to an embodiment of the present disclosure, a semiconductor device may include a target layer; and a hard mask on the target layer. The hard mask may include an amorphous carbon layer having a first layer and a second layer on the first layer. An extinction coefficient of the hard mask may be in a range of 0.4 to 0.7. The first layer may have a first extinction coefficient. The second layer may have a second extinction coefficient. The second extinction coefficient may be different from the first extinction coefficient.

### BRIEF DESCRIPTION OF DRAWINGS

The above and other aspects and features of the present disclosure will become more apparent by describing in detail illustrative embodiments thereof with reference to the attached drawings, in which:

FIG. 1 is a diagram for illustrating a semiconductor device according to some embodiments.

FIG. 2 is a diagram for illustrating a hard mask according to some embodiments.

FIG. 3 is a diagram for illustrating a hard mask according to some embodiments.

FIG. 4 is a diagram for illustrating a hard mask according to some embodiments.

FIG. 5 is a diagram for illustrating a hard mask according to some embodiments.

FIG. 6 is a diagram for illustrating a hard mask according to some embodiments.

FIG. 7 is a graph showing an experimental result for illustrating a hard mask according to some embodiments.

FIG. 8 is a graph showing an experimental result for illustrating a hard mask according to some embodiments.

FIG. 9 is a flowchart for illustrating a hard mask manufacturing method according to some embodiments.

FIG. 10 to FIG. 13 are diagrams for illustrating a method for manufacturing a semiconductor device using a hard mask according to some embodiments.

FIG. 14 and FIG. 15 are diagrams for illustrating a method for manufacturing a semiconductor device using a hard mask according to some embodiments.

FIG. 16 is a block diagram illustrating a memory card having a semiconductor device according to some embodiments.

FIG. 17 is a block diagram illustrating an information processing system to which a semiconductor device according to some embodiments of the present disclosure is applied.

### DETAILED DESCRIPTION

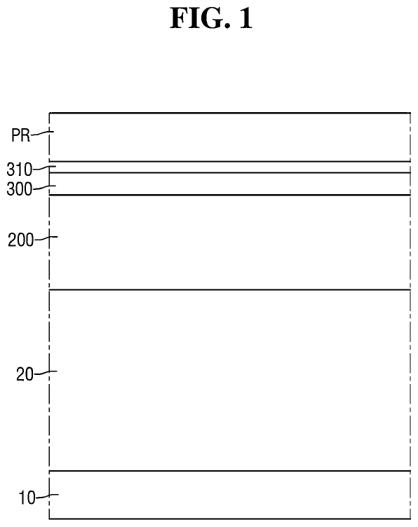

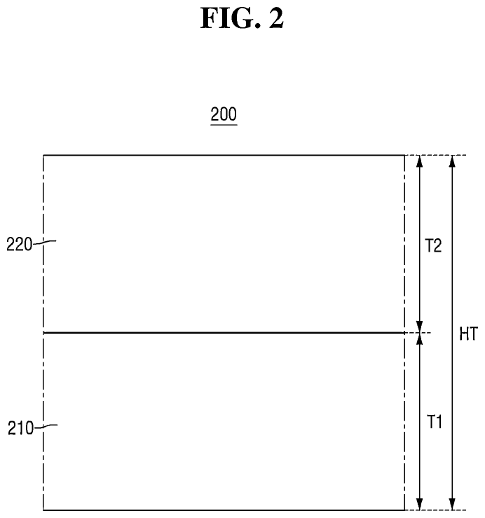

FIG. 1 is a diagram for illustrating a semiconductor device according to some embodiments. FIG. 2 is a diagram for illustrating a hard mask according to some embodiments.

Referring to FIG. 1, a semiconductor device according to some embodiments may include a substrate 10, an etching target layer 20, a hard mask 200, a silicon oxynitride layer 300, an anti-reflective layer 310, and a photoresist PR.

The substrate 10 may include, for example, a semiconductor substrate such as a silicon substrate, a germanium substrate or a silicon-germanium substrate. Alternatively, the substrate 10 may include a silicon-on-insulator (SOI) substrate or a germanium-on-insulator (GOI) substrate. In some embodiments, the substrate 10 may contain impurities. For example, the substrate 10 may include n-type impurities such as phosphorus (P), arsenic (As), or the like.

The etching target layer 20 may be disposed on the substrate 10. The etching target layer 20 may be etched in a patterning process using the hard mask 200. The etching target layer 20 may be embodied as, for example, a conductive layer, a dielectric layer, an insulating layer, or a combination thereof. In some embodiments, the etching target layer 20 may be made of metal, alloy, metal carbide, metal nitride, metal oxynitride, metal oxycarbide, semiconductor, polysilicon, oxide, nitride, oxynitride, or combinations thereof. However, the present disclosure is not limited thereto.

Although the etching target layer 20 is shown as a single layer, the present disclosure is not limited thereto. The etching target layer 20 may be embodied as, for example, a stack in which a plurality of semiconductor layers and a plurality of insulating layers are alternately stacked on top of each other. The etching target layer 20 may be embodied as, for example, a stack in which a plurality of silicon nitride layers and a plurality of silicon oxide layers alternately stacked on top of each other.

The hard mask 200 may be disposed on the etching target layer 20. The hard mask 200 may cover the etching target layer 20. The hard mask 200 may include, for example, an amorphous carbon layer (ACL). The hard mask 200 may be patterned using the photoresist PR layer as an etch mask. The patterned hard mask 200 may be used as a mask pattern for the etching target layer 20.

The hard mask 200 is shown as a single layer. However, the hard mask 200 may include a plurality of layers. A configuration of the plurality of layers is described in detail with reference to FIG. 2 to FIG. 6. The hard mask 200 may be formed by, for example, a plasma enhanced chemical vapor deposition (PECVD) process. The hard mask 200 may be deposited using a hydrocarbon gas (e.g., a C₃H₆ gas). The hard mask 200 including the plurality of layers may be formed by changing a process condition for depositing the hard mask 200. For example, the plurality of layers having different thin-film characteristics may be formed by changing a pressure.

The silicon oxynitride layer 300 may be disposed on the hard mask 200. The silicon oxynitride layer 300 may cover the hard mask 200. The silicon oxynitride layer 300 may include silicon oxynitride (SiON). The silicon oxynitride layer 300 may be formed by, for example, spin coating.

The anti-reflective layer 310 may be disposed on the silicon oxynitride layer 300. The anti-reflective layer 310 may cover the silicon oxynitride layer 300. The anti-reflective layer 310 may limit and/or prevent total reflection of light during a subsequent exposure process. Any material used in a typical photo lithography process may be used as a material constituting the anti-reflective layer 310.

The anti-reflective layer 310 may be made of, for example, an organic ARC (anti-reflective coating) material for a KrF excimer laser, an ArF excimer laser, or any other light source. The anti-reflective layer 310 may be made of an ARC material used in a dry lithography process or an ARC material used in an immersion lithography process.

In some embodiments, the anti-reflective layer 310 may be an inorganic anti-reflective layer or an organic anti-reflective layer. The inorganic anti-reflective layer may be made of, for example, titanium, titanium dioxide, titanium nitride, chromium oxide, carbon, silicon nitride, silicon oxynitride, amorphous silicon, or a combination thereof.

The photoresist PR may be disposed on the anti-reflective layer 310. The photoresist PR may cover the anti-reflective layer 310. The photoresist PR may be converted to a photoresist pattern via exposure and development processes. The photoresist pattern may be used as an etching mask.

The photoresist PR may include, for example, an organic photoresist including an organic polymer such as polyhydroxystyrene. The organic photoresist may further include a photosensitive compound that reacts to extreme ultraviolet (EUV). The organic photoresist may further include a material having high EUV absorption, for example, an organometallic material, an iodine-containing material, or a fluorine-containing material. The photoresist PR may include, for example, an inorganic photoresist including an inorganic material such as tin oxide. However, the present disclosure is not limited thereto.

Referring to FIG. 2, the hard mask 200 according to some embodiments may include a first layer 210 and a second layer 220.

The hard mask 200 may include an amorphous carbon layer. An extinction coefficient of the hard mask 200 may be in a range of 0.4 to 0.7. As used herein, the extinction coefficient may be a measurement value using a laser having a wavelength of 633 nm (nanometer). A thickness HT of the hard mask 200 may be in a range of 1500 Å angstrom to 80000 Å. The thickness of the hard mask 200 may vary depending on a manufacturing scheme of the semiconductor device.

The first layer 210 may include an amorphous carbon layer. The first layer 210 may have a first extinction coefficient K1. The first extinction coefficient K1 may be in a range of 0.4 to 0.7. The first layer 210 may have a first thickness T1.

The second layer 220 may be disposed on the first layer 210. A boundary between the first layer 210 and the second layer 220 may not be defined. The second layer 220 may include an amorphous carbon layer. The second layer 220 may have a second extinction coefficient K2. The second extinction coefficient K2 may be in a range of 0.4 to 0.7. The second layer 220 may have a second thickness T2.

The first layer 210 and the second layer 220 may be formed consecutively. For example, the first layer 210 may be formed at a first pressure in a chemical vapor deposition (CVD) process, and then the second layer 220 may be formed at a second pressure different from the first pressure using the CVD process.

In some embodiments, the second extinction coefficient K2 is different from the first extinction coefficient K1. That is, the hard mask 200 may include the first layer 210 and the second layer 220 having different extinction coefficients. The hard mask 200 can reduce the wafer stress and/or improve the etch selectivity, compared to a hard mask made of a single layer. In this regard, the wafer stress is a compressive stress applied to the wafer in a process using the hard mask 200.

In some embodiments, the first extinction coefficient K1 may be smaller than the second extinction coefficient K2. For example, the first extinction coefficient K1 may be 0.4, and the second extinction coefficient K2 may be 0.6. In this case, the etch selectivity may be improved compared to that when a hard mask made of a single layer having an extinction coefficient of 0.5 is used. It should be appreciated that the above-described values of the first extinction coefficient K1 and the second extinction coefficient K2 are merely examples. Technical ideas of the present disclosure are not limited thereto.

A sum of the first thickness T1 and the second thickness T2 may be the thickness HT of the hard mask 200. In some embodiments, a percentage of the first thickness T1 in the thickness HT of the hard mask 200 may be in a range of 10% to 90%. Similarly, a percentage of the second thickness T2 in the thickness HT of the hard mask 200 may be in a range of 10% to 90%. In other words, depending on a manufacturing scheme of the hard mask 200, each of the first thickness T1 and the second thickness T2 may vary. A minimum value of each of the first thickness T1 and the second thickness T2 may be 10% of the thickness HT of the hard mask 200.

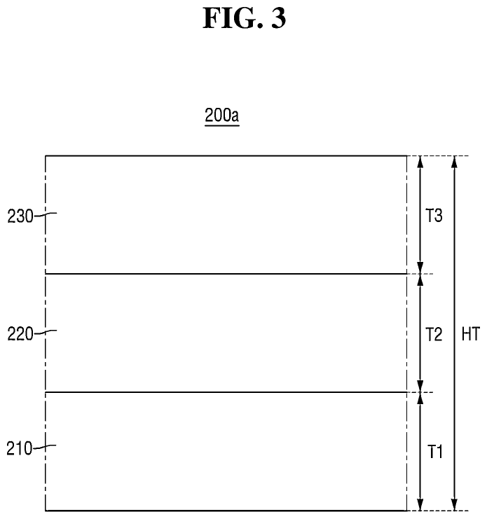

FIG. 3 is a diagram for illustrating a hard mask according to some embodiments. For convenience of description, those duplicate with the descriptions as set forth above with reference to FIG. 2 are briefly described or omitted.

Referring to FIG. 3, a hard mask 200a according to some embodiments may include the first layer 210, the second layer 220, and a third layer 230.

The third layer 230 may be disposed on the second layer 220. The second layer 220 may be disposed between the first layer 210 and the third layer 230. A boundary between the second layer 220 and the third layer 230 may not be defined. The third layer 230 may include an amorphous carbon layer. The third layer 230 may have a third extinction coefficient K3. The third extinction coefficient K3 may be in a range of 0.4 to 0.7. The third layer 230 may have a third thickness T3.

In some embodiments, the first extinction coefficient K1 and the third extinction coefficient K3 may be equal to each other. The second extinction coefficient K2 may be smaller than each of the first extinction coefficient K1 and the third extinction coefficient K3. For example, each of the first extinction coefficient K1 and the third extinction coefficient K3 may be 0.6, while the second extinction coefficient K2 may be 0.4. In this case, the wafer stress can be reduced compared to that when a hard mask made of a single layer having an extinction coefficient of 0.5 is used. It should be appreciated that the above-described values of the first to third extinction coefficients K1, K2, and K3 are examples. Technical ideas of the present disclosure are not limited thereto.

In some embodiments, the first extinction coefficient K1 may be different from the third extinction coefficient K3. For example, the third extinction coefficient K3 may be greater than the second extinction coefficient K2, which may be greater than the first extinction coefficient K1. In this case, the hard mask 200a can reduce the wafer stress and can improve the etch selectivity, compared to a hard mask made of a single layer.

A sum of the first thickness T1, the second thickness T2, and the third thickness T3 may be a thickness HT of the hard mask 200a. Depending on a manufacturing scheme of the hard mask 200a, each of the first thickness T1, the second thickness T2, and the third thickness T3 may vary. A minimum value of each of the first thickness T1, the second thickness T2, and the third thickness T3 may be 10% of the thickness HT of the hard mask 200a.

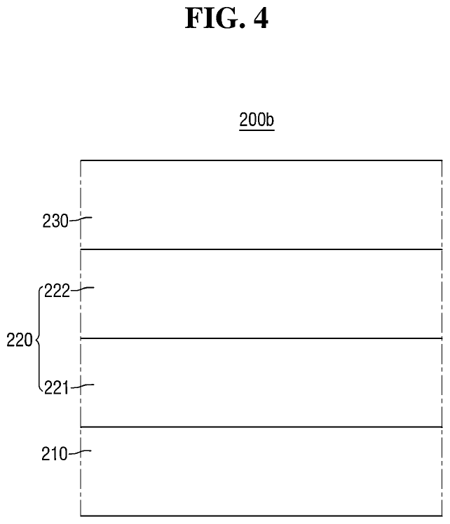

FIG. 4 is a diagram for illustrating a hard mask according to some embodiments. For convenience of description, those duplicate with the descriptions as set forth above with reference to FIG. 2 and FIG. 3 are briefly described or omitted.

Referring to FIG. 4, a hard mask 200b according to some embodiments may include the first layer 210, the second layer 220, and the third layer 230.

The second layer 220 may include a first sub-layer 221 and a second sub-layer 222. The first sub-layer 221 may be disposed on the first layer 210. The second sub-layer 222 may be disposed on the first sub-layer 221.

The first sub-layer 221 may have a fourth extinction coefficient K4. The second sub-layer 222 may have a fifth extinction coefficient K5. The fourth extinction coefficient K4 is different from the fifth extinction coefficient K5. Each of the fourth extinction coefficient K4 and the fifth extinction coefficient K5 may be in a range of 0.4 to 0.7.

In some embodiments, the third extinction coefficient K3 may be greater than the fifth extinction coefficient K5. The fifth extinction coefficient K5 may be greater than the fourth extinction coefficient K4. The fourth extinction coefficient K4 may be greater than the first extinction coefficient K1. That is, the extinction coefficient values of the layers may decrease as the hard mask 200b extends in a direction from the third layer 230 to the first layer 210. In this case, the hard mask 200b can reduce the wafer stress and improve the etch selectivity compared to a hard mask made of a single layer.

Depending on a manufacturing scheme of the hard mask 200b, each of the first thickness T1, the third thickness T3, a thickness of the first sub-layer 221, and a thickness of the second sub-layer 222 may vary. A minimum value of each of the first thickness T1, the third thickness T3, the thickness of the first sub-layer 221 and the thickness of the second sub-layer may be 10% of the thickness HT of the hard mask 200b.

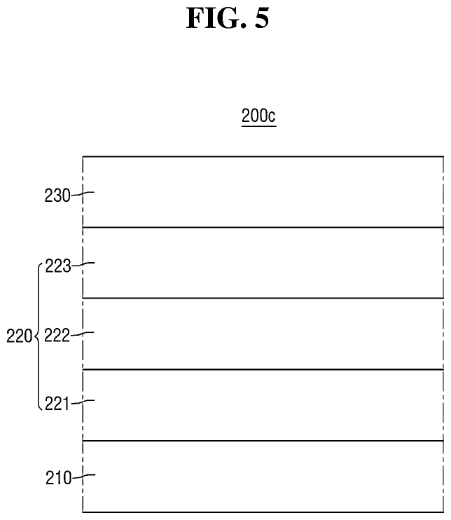

FIG. 5 is a diagram for illustrating a hard mask according to some embodiments. For convenience of description, those duplicate with the descriptions as set forth above with reference to FIG. 2 to FIG. 4 are briefly described or omitted.

Referring to FIG. 5, a hard mask 200c according to some embodiments may include the first layer 210, the second layer 220, and the third layer 230.

The second layer 220 may include the first sub-layer 221, the second sub-layer 222, and a third sub-layer 233. The third sub-layer 233 may be disposed on the second sub-layer 222. The second sub-layer 222 may be disposed between the first sub-layer 221 and the third sub-layer 223.

The third sub-layer 223 may have a sixth extinction coefficient K6. The sixth extinction coefficient K6 is different from the fifth extinction coefficient K5. The sixth extinction coefficient K6 may be in a range of 0.4 to 0.7.

In some embodiments, the sixth extinction coefficient K6 may be smaller than the third extinction coefficient K3. The fifth extinction coefficient K5 may be smaller than the sixth extinction coefficient K6. The fourth extinction coefficient K4 may be smaller than the fifth extinction coefficient K5. The first extinction coefficient K1 may be smaller than the fourth extinction coefficient. That is, the extinction coefficient values of the layers may decrease as the hard mask 200c extends in a direction from the third layer 230 to the first layer 210. In this case, the hard mask 200c can reduce the wafer stress and improve the etch selectivity compared to a hard mask made of a single layer.

In some embodiments, the sixth extinction coefficient K6 may be equal to the fourth extinction coefficient K4. The fifth extinction coefficient K5 may be smaller than the sixth extinction coefficient K6. The sixth extinction coefficient K6 may be smaller than the third extinction coefficient K3. The first extinction coefficient K1 may be smaller than the fourth extinction coefficient K4. That is, the fifth extinction coefficient K5 of the second sub-layer 222 among the layers of the hard mask 200c may be the smallest.

Depending on the manufacturing scheme of the hard mask 200c, each of the first thickness T1, the third thickness T3, and a thickness of each of the first to third sub-layers 221, 222, and 223 may vary. A minimum value of each of the first thickness T1, the third thickness T3, and the thickness of each of the first to third sub-layers 221, 222, and 223 may be 10% of the thickness HT of the hard mask 200c.

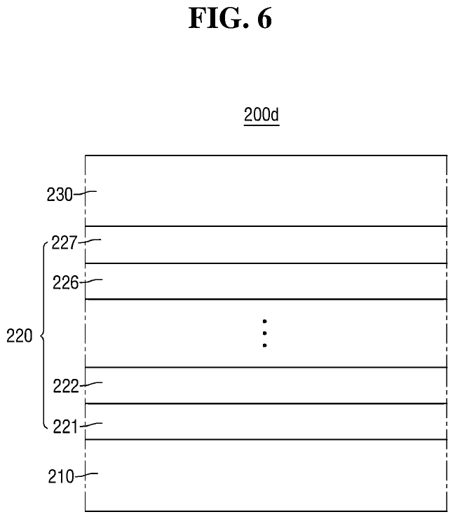

FIG. 6 is a diagram for illustrating a hard mask according to some embodiments. For convenience of description, those duplicate with the descriptions as set forth above with reference to FIG. 2 to FIG. 4 are briefly described or omitted.

Referring to FIG. 6, a hard mask 200d may include the first layer 210, the second layer 220, and the third layer 230.

The second layer 220 may include the first to seventh sub-layers 221 to 227. However, the present disclosure is not limited thereto. For example, the number of sub-layers of the second layer 220 may vary.

An extinction coefficient of each of the first to seventh sub-layers 221 to 227 may be in a range of 0.4 to 0.7. Each of the first to seventh sub-layers 221 to 227 have an extinction coefficient value different from that of each of the sub-layer and the layer adjacent thereto. For example, the extinction coefficient of the first sub-layer 221 is different from the extinction coefficient of the second sub-layer 222, and is different from the extinction coefficient of the first layer 210. The extinction coefficient of the seventh sub-layer 227 is different from the extinction coefficient of the sixth sub-layer 226, and is different from the extinction coefficient of the third layer 230.

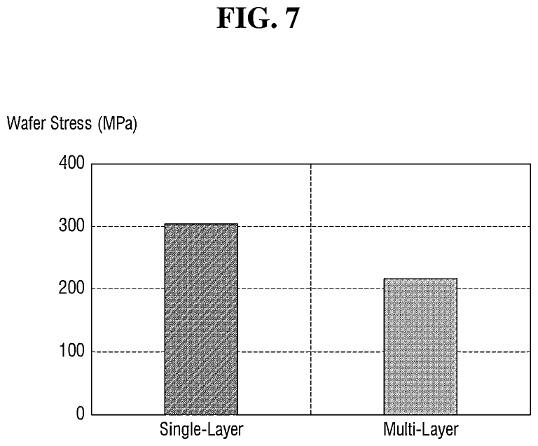

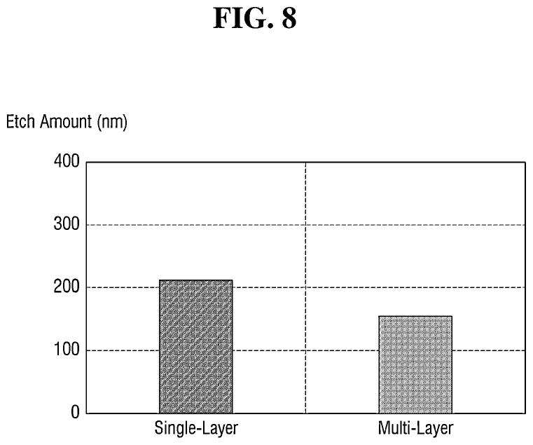

FIG. 7 is a graph showing an experimental result for illustrating a hard mask according to some embodiments. FIG. 8 is a graph showing an experimental result for illustrating a hard mask according to some embodiments.

Referring to FIG. 7, the graph is the experimental result of measuring the wafer stress when a process is performed using each of two hard masks. The experiment is conducted while the two hard masks have the same thickness and etch rates thereof are the same. In this regard, the wafer stress refers to a compressive stress applied to the wafer.

A wafer stress value when using a single-layer hard mask is greater than that when using a multi-layer hard mask. The single-layer hard mask may have, for example, an extinction coefficient of 0.54. The multi-layer hard mask may be, for example, the hard mask 200a in FIG. 3 in which each of the first extinction coefficient K1 and the third extinction coefficient K3 may be 0.54 and the second extinction coefficient K2 may be 0.51. In other words, the wafer stress can be reduced when using the multi-layer hard mask, compared to that when using the single-layer hard mask. Thus, when using the multi-layer hard mask, the chucking error and the arcing related defect of the wafer can be reduced.

Referring to FIG. 8, the graph is the experimental result of measuring an etched amount when the process is performed using two hard masks. In this regard, the etched amount may be based on an etched depth for the same time.

The etched amount when using the single-layer hard mask is greater than the etched amount when using the multi-layer hard mask. The single-layer hard mask may have, for example, an extinction coefficient of 0.51. The hard mask may be, for example, the hard mask 200 in FIG. 2 in which the first extinction coefficient K1 may be 0.51, and the second extinction coefficient K2 may be 0.54. That is, the etched amount can be reduced when the multi-layer hard mask is used, compared to when the single-layer hard mask is used. Thus, when the multi-layer hard mask is used, film quality thereof against the etching may be improved.

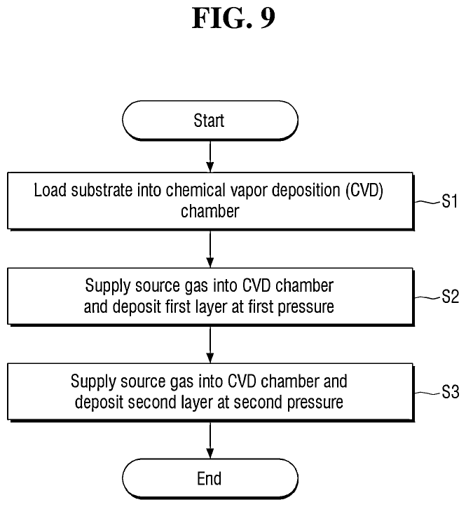

FIG. 9 is a flowchart for illustrating a hard mask manufacturing method according to some embodiments. For reference, FIG. 9 may be used to illustrate the manufacturing method of the hard mask 200 in FIG. 2.

Referring to FIG. 1, 2 and FIG. 9, a substrate is loaded into a chemical vapor deposition (CVD) chamber in S1. In this regard, the substrate may be the substrate 10 in FIG. 1. The substrate may be loaded into the chamber while the etching target layer 20 has been formed on the substrate. The chemical vapor deposition (CVD) may be, for example, a plasma chemical vapor deposition (PECVD). However, the present disclosure is not limited thereto.

Subsequently, a source gas is supplied to the CVD chamber and the first layer 210 is deposited at a first pressure P1 in S2. The first pressure P1 may range from 1 Torr to 15 Torr. A temperature at which the first layer is deposited may range from 500 degrees to 700 degrees. The source gas may be a gas containing carbon (C) and hydrogen (H). The source gas may be, for example, C₃H₆ gas. However, the present disclosure is not limited thereto. The first thickness T1 of the first layer 210 may be proportional to a deposition time of the first layer 210.

Subsequently, a source gas is supplied to the CVD chamber and the second layer 220 is deposited at a second pressure P2 in S3. Thus, the second layer 220 may be deposited to form the hard mask 200. The second pressure P2 is different from the first pressure P1. The second pressure P2 may range from 1 Torr to 15 Torr. The temperature at which the first layer is deposited may range from 500 degrees to 700 degrees. In S3, the source gas may be a gas containing carbon (C) and hydrogen (H). The source gas used for the deposition of the second layer 220 is the same as that used for the deposition of the first layer 210. The second thickness T2 of the second layer 220 may be proportional to a deposition time of the second layer 220.

The process of depositing the first layer 210 and the process of depositing the second layer 220 may be continuously performed. A process temperature for depositing the first layer 210 and a process temperature for depositing the second layer 220 may be equal to each other. However, the present disclosure is not limited thereto. For example, the first layer 210 and the second layer 220 may be deposited at different temperatures.

In one embodiment, the first pressure P1 is greater than the second pressure P2. In this case, the first extinction coefficient K1 of the first layer 210 is smaller than the second extinction coefficient K2 of the second layer 220.

In another embodiment, the first pressure P1 is lower than the second pressure P2. In this case, the first extinction coefficient K1 of the first layer 210 is greater than the second extinction coefficient K2 of the second layer 220.

The description about each of the hard masks 200a, 200b, 200c, and 200d in FIG. 3 to FIG. 6 may be similar to that about FIG. 9. For example, when forming the hard mask 200a in FIG. 3 including the third layer 230, the third layer 230 is deposited under a pressure different from the second pressure P2. Similarly, the first sub-layer 221 and the second sub-layer 222 are deposited under different pressures.

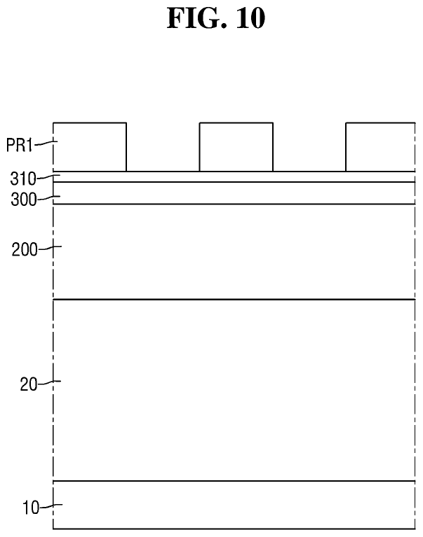

FIG. 10 to FIG. 13 are diagrams for illustrating a method for manufacturing a semiconductor device using a hard mask according to some embodiments.

Hereinafter, the hard mask 200 as described below may employ the hard mask as described with reference to each of FIG. 2 to FIG. 6.

Referring to FIG. 1 and FIG. 10, the photoresist PR may be converted to a photoresist pattern PRI using exposure and development processes. The photoresist pattern PRI may be formed on the anti-reflective layer 310. The photoresist pattern PRI may expose a portion of the anti-reflective layer 310.

In order to form the photoresist pattern PRI, a portion of the photoresist PR is exposed to light to form an exposed photoresist PR including a non-exposed area and an exposed area. The photoresist pattern PRI may be formed by performing a PEB (post-exposure baking) process on the exposed photoresist PR.

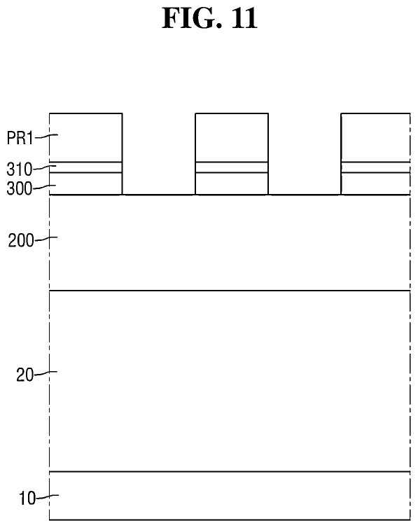

Referring to FIG. 11, the anti-reflective layer 310 and the silicon oxynitride layer 300 may be patterned using the photoresist pattern PRI as an etching mask.

For example, the anti-reflective layer 310 may be patterned using the photoresist pattern PRI as an etching mask. For example, an ashing process may be performed such that a patterning process may be performed to remove the exposed portion of the anti-reflective layer 310.

Subsequently, the silicon oxynitride layer 300 may be patterned using the patterned anti-reflective layer 310 as an etching mask. In order to pattern the silicon oxynitride layer 300, for example, CₓF_{y} gas or CHₓF_{y} gas may be used.

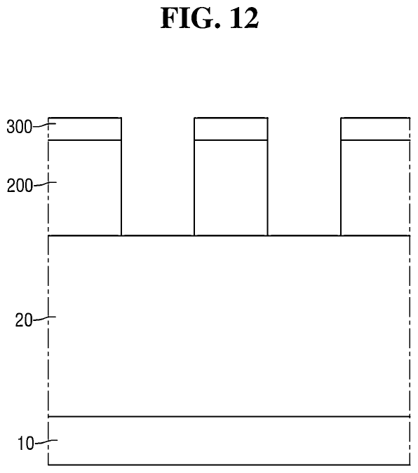

Referring to FIG. 12, the anti-reflective layer 310 may be removed, and then the hard mask 200 may be patterned using the silicon oxynitride layer 300 as an etching mask. In this regard, the hard mask 200 may be any one of the hard masks 200, 200a, 200b, 200c, and 200d as described with reference to FIG. 2 to FIG. 6.

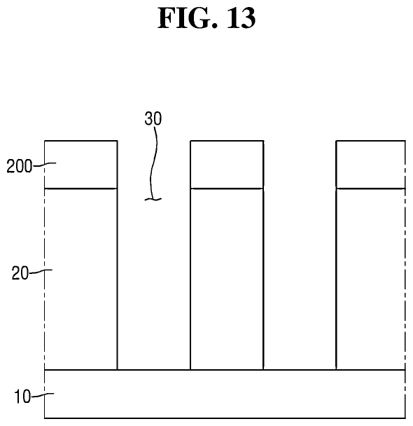

Referring to FIG. 13, the etching target layer 20 may be etched using the patterned hard mask 200 as an etching mask. For example, when the etching target layer 20 is made of a silicon-based material, the etching may be performed using CₓF_{y} gas or CHₓF_{y} gas as an etching gas. An exposed portion of the etching target layer 20 may be etched to form a hole 30. The hole 30 may be, for example, a high aspect ratio contact-hole (HARC). While the hole 30 is being formed, a thickness of the hard mask 200 may be reduced.

In some embodiments, the hole 30 may be a contact hole for forming a capacitor connected to a switching element formed in the substrate 10.

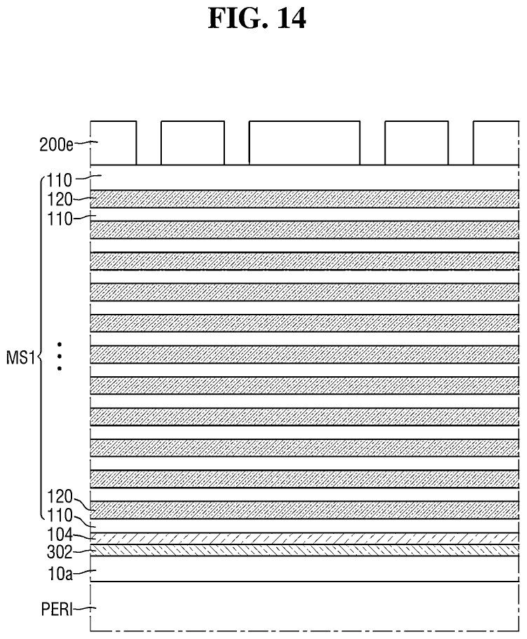

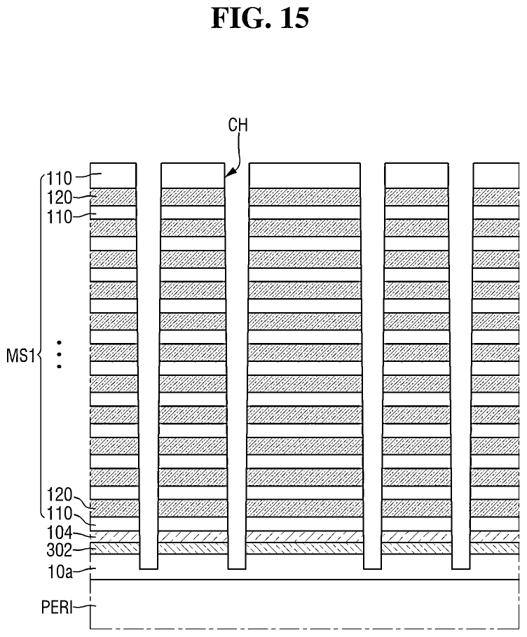

FIG. 14 and FIG. 15 are diagrams for illustrating a method for manufacturing a semiconductor device using a hard mask according to some embodiments.

Referring to FIG. 14, a cell substrate 10a is formed on a peripheral structure PERI. A sacrificial semiconductor layer 302 and a second source layer 104 are formed on the cell substrate 10a. A mold structure MS1 is formed on the second source layer 104. The mold structure MS1 may be formed by alternately stacking a plurality of mold insulating layers 110 and a plurality of semiconductor layers 120 on top of each other.

The cell substrate 10a may include, for example, a semiconductor substrate such as a silicon substrate, a germanium substrate or a silicon-germanium substrate. Alternatively, the cell substrate 10a may include a silicon-on-insulator (SOI) substrate or a germanium-on-insulator (GOI) substrate. In some embodiments, the cell substrate 10a may contain impurities. For example, the cell substrate 10a may contain n-type impurities such as phosphorus (P), arsenic (As), or the like.

The peripheral structure PERI may include a peripheral logic structure. The peripheral logic structure may constitute a peripheral circuit that controls an operation of the semiconductor memory device. The peripheral logic structure may include various active elements such as transistors, active elements, and various passive elements such as capacitors, resistors, and inductors.

Although not shown, an etch stop film may be formed on the cell substrate 10a. The etch stop film may be formed using an insulating material such as, for example, silicon oxide, silicon nitride, or silicon oxynitride. However, the present disclosure is not limited thereto.

In some embodiments, each of the sacrificial semiconductor layer 302 and the plurality of semiconductor layers 120 may be formed using a conductive material such as doped poly silicon. The sacrificial semiconductor layer 302 and the plurality of semiconductor layers 120 may have different thicknesses and/or spacings therebetween.

Subsequently, a hard mask 200e is formed on the mold structure MS1. A formation method of the hard mask 200e may be the same as that described with reference to FIG. 10.

Referring to FIG. 15, anisotropic etching may be performed on the cell substrate 10a, the sacrificial semiconductor layer 302, the second source layer 104, and the mold structure MS1 using the hard mask 200e as an etching mask to form a channel hole CH. The channel hole CH may be a channel hole for forming a vertical semiconductor memory device such as NAND.

The semiconductor device manufactured using the hard mask 200 of the present disclosure is not limited to the semiconductor device as described with reference to FIG. 10 to FIG. 15. The hard mask 200 may also be used in a manufacturing process of DRAM (Dynamic Random Access Memory), for example, a process of forming a bit line structure or a capacitor of the DRAM. Further, it may be appreciated that the hard mask 200 may be used in a process of forming a pattern of each of GAAFET (Gate All Around FET) and Fin-FET. Thus, it is obvious that the hard mask 200 of the present disclosure may be used for a method for manufacturing any semiconductor device easily conceivable by a person skilled in the art.

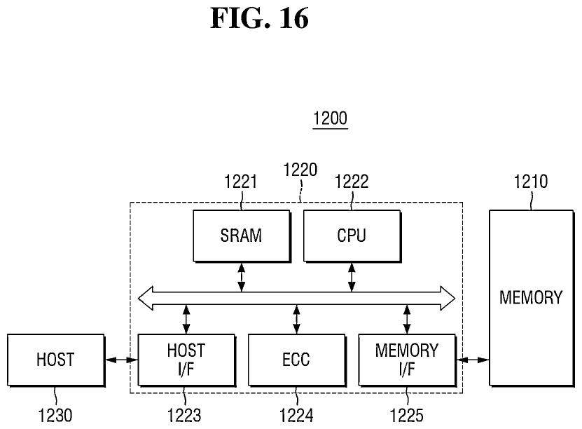

FIG. 16 is a block diagram illustrating a memory card having a semiconductor device according to some embodiments.

Referring to FIG. 16, the semiconductor device according to some embodiments of the present disclosure may be applied to a memory card 1200.

The memory card 1200 may include a memory controller 1220 that controls data exchange between a host 1230 and a memory 1210. A SRAM 1221 may be used as a working memory of a central processing unit 1222. A host interface 1223 may have a data exchange protocol of the host 1230 connected to the memory card 1200. An error correction code 1224 may detect and correct an error included in data read from the memory 1210. The memory interface 1225 may interface with the memory 1210. The central processing unit 1222 may perform various control operations for data exchange of the memory controller 1220.

For example, at least one of the memory 1210 and the central processing unit 1222 may include at least one of the semiconductor devices according to some embodiments of the present disclosure.

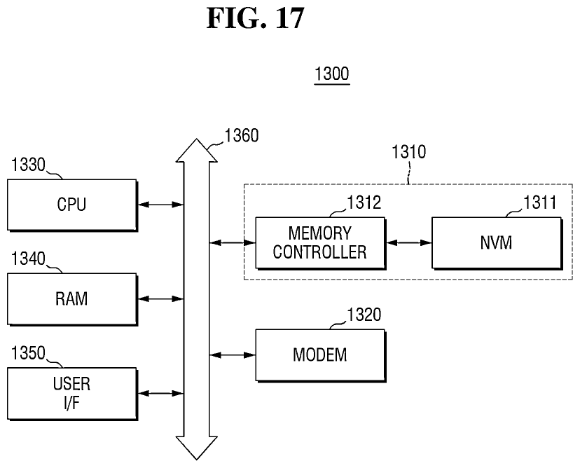

FIG. 17 is a block diagram illustrating an information processing system to which a semiconductor device according to some embodiments of the present disclosure is applied.

Referring to FIG. 17, the semiconductor device according to the embodiments of the present disclosure may be applied to an information processing system 1300.

The information processing system 1300 may include a mobile device or a computer, etc. The information processing system 1300 may include a memory system 1310, a modem 1320, a central processing unit 1330, a RAM 1340, and a user interface 1350 electrically connected to a system bus 1360. The memory system 1310 may include a memory 1311 and a memory controller 1312, and may be configured substantially in the same manner as a manner in which the memory card 1200 of FIG. 16 is configured. Further, at least one of the central processing unit 1330 and the RAM 1340 may include at least one of the semiconductor devices according to some embodiments of the present disclosure.

Data processed by the central processing unit 1330 or data input from an external device may be stored in the memory system 1310. The memory system 1310 may be embodied as a memory card, a semiconductor disk device (Solid State Disk), a camera image processor, a camera image sensor, or other application chipsets. In one example, the memory system 1310 may include a semiconductor disk device (SSD). In this case, the information processing system 1300 may stably and reliably store a large amount of data in the memory system 1310.

One or more of the elements disclosed above may include or be implemented in processing circuitry such as hardware including logic circuits: a hardware/software combination such as a processor executing software: or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

In concluding the detailed description, those skilled in the art will appreciate that many variations and modifications may be made to example embodiments without substantially departing from the principles and aspects of inventive concepts. Therefore, the presented embodiments are provided in a generic and descriptive sense only and not for purposes of limitation.

What is claimed is:

1. A hard mask comprising:
a first layer; and
a second layer on the first layer, wherein
the first layer and the second layer each include an amorphous carbon layer,
the first layer has a first extinction coefficient,
the second layer has a second extinction coefficient,
the second extinction coefficient is different from the first extinction coefficient,
the first extinction coefficient and the second extinction coefficient each are in a range of 0.4 to 0.7.

2. The hard mask of claim 1, wherein the first extinction coefficient is smaller than the second extinction coefficient.

3. The hard mask of claim 1, further comprising:
a third layer on the second layer, wherein
the second layer is between the first layer and the third layer,
the third layer has a third extinction coefficient, and
the third extinction coefficient is different from the second extinction coefficient.

4. The hard mask of claim 3, wherein the first extinction coefficient and the third extinction coefficient are equal to each other.

5. The hard mask of claim 4, wherein the second extinction coefficient is smaller than the first extinction coefficient.

6. The hard mask of claim 4, wherein
the second layer includes a first sub-layer having a fourth extinction coefficient and a second sub-layer having a fifth extinction coefficient,
the fourth extinction coefficient is smaller than the first extinction coefficient, and
the fifth extinction coefficient is smaller than the first extinction coefficient.

7. The hard mask of claim 1, further comprising:
a third layer on the second layer, wherein
the second layer is between the first layer and the third layer,
the third layer has a third extinction coefficient, and
the third extinction coefficient is different from the first extinction coefficient.

8. The hard mask of claim 1, further comprising:
a third layer on the second layer, wherein
the second layer is between the first layer and the third layer,
the third layer has a third extinction coefficient,
the first extinction coefficient is smaller than the second extinction coefficient, and
the second extinction coefficient is smaller than the third extinction coefficient.

9. The hard mask of claim 8, wherein
the second layer includes a first sub-layer having a fourth extinction coefficient and a second sub-layer having a fifth extinction coefficient, and
the fourth extinction coefficient is different from the fifth extinction coefficient.

10. The hard mask of claim 9, wherein
the fourth extinction coefficient is greater than the first extinction coefficient, and
the fifth extinction coefficient is smaller than the third extinction coefficient.

11. The hard mask of claim 8, wherein
the second layer includes a first sub-layer having a fourth extinction coefficient, a second sub-layer having a fifth extinction coefficient, and a third sub-layer having a sixth extinction coefficient,
the sixth extinction coefficient is smaller than the third extinction coefficient,
the fifth extinction coefficient is smaller than the sixth extinction coefficient,
the fourth extinction coefficient is smaller than the fifth extinction coefficient, and
the first extinction coefficient is smaller than the fourth extinction coefficient.

12. A hard mask on a substrate, the hard mask comprising:
an amorphous carbon layer having a first layer and a second layer on the first layer, wherein
an extinction coefficient of the hard mask is in a range of 0.4 to 0.7,
the first layer has a first extinction coefficient,
the second layer has a second extinction coefficient, and
the second extinction coefficient is different from the first extinction coefficient.

13. The hard mask of claim 12, wherein the hard mask has a thickness in a range of 1500 Å to 80000 Å.

14. The hard mask of claim 12, further comprising:
a third layer on the second layer, wherein
the third layer has a third extinction coefficient,
the second layer is disposed between the first layer and the third layer, and
the third extinction coefficient is different from the second extinction coefficient.

15. The hard mask of claim 14, wherein a thickness of the second layer is in a range of 10% to 40% of a total thickness of the hard mask.

16. The hard mask of claim 14, wherein the first layer and the third layer have a same thickness.

17. The hard mask of claim 14, wherein
a thickness of the second layer is smaller than a thickness of the first layer, and the thickness of the second layer is smaller than a thickness of the third layer.

18. The hard mask of claim 12, wherein each of the first extinction coefficient and the second extinction coefficient is in a range of 0.4 to 0.7.

19. A hard mask on a target layer, the hard mask comprising
an amorphous carbon layer having a first layer and a second layer on the first layer, wherein
an extinction coefficient of the hard mask is in a range of 0.4 to 0.7,
the first layer has a first extinction coefficient,
the second layer has a second extinction coefficient, and
the second extinction coefficient is different from the first extinction coefficient,
wherein the target mask includes semiconductor layer.

20. The hard mask of claim 19, wherein the target layer includes a plurality of semiconductor layers and a plurality of mold insulating layers alternately stacked on top of each other.
